(19) United States
(12) Patent Application Publication
(10) Pub. No.: US 2026/0282485 A1
(43) Pub. Date: Sep. 17, 2026

(54) SEMICONDUCTOR DEVICE AND METHOD FOR MANUFACTURING THE SAME

(71) Applicants: Kabushiki Kaisha Toshiba, Kawasaki-shi (JP); Toshiba Electronic Devices & Storage Corporation, Kawasaki-shi (JP)

(72) Inventors: Takuya YASUTAKE, Kanazawa Ishikawa (JP); Naoki ASANO, Nonoichi Ishikawa (JP); Tsuyoshi KACHI, Kanazawa Ishikawa (JP); Kenji MAEYAMA, Kanazawa Ishikawa (JP); Masataka INO, Oita Oita (JP); Toshifumi NISHIGUCHI, Hakusan Ishikawa (JP)

(21) Appl. No.: 19/562,624

(22) Filed: Mar. 10, 2026

(30) Foreign Application Priority Data
Mar. 14, 2025 (JP) 2025-041141

(51) Int. Cl. H10D 64/23; H10D 30/66; H10D 62/00; H10D 62/10; H10D 62/13; H10D 64/00; H10D 64/01; H10D 64/62

(52) U.S. Cl. CPC H10D 64/2527; H10D 30/66; H10D 62/021; H10D 62/116; H10D 62/155; H10D 64/01125; H10D 64/117; H10D 64/62

(57) ABSTRACT

The semiconductor device according to the embodiment includes a plurality of gate electrodes, a semiconductor portion and a first electrode. The plurality of gate electrodes is arranged along a first direction. The semiconductor portion is including a first conductivity type semiconductor region provided between the plurality of gate electrodes. The first electrode has a contact portion in contact with the semiconductor region between the plurality of gate electrodes. The semiconductor region includes a first portion having a first width in the first direction and a second portion provided alternately with the first portion in a second direction orthogonal to the first direction. The second portion has a second width in the first direction. The first width is smaller than the second width.

### CROSS-REFERENCE TO RELATED APPLICATION

This application is based upon and claims the benefit of priority from Japanese Patent Application No.2025-041141, filed on Mar. 14, 2025; the entire contents of which are incorporated herein by reference.

### FIELD

Embodiments of the invention generally relate to a semiconductor device and a method for manufacturing the same.

### BACKGROUND

In semiconductor devices such as MOSFET (Metal Oxide Semiconductor Field Effect Transistor), a trench contact structure is known in which a part of a source electrode contacts a p+ type semiconductor region between trench-type gate electrodes. In this trench contact structure, the p+ type semiconductor region faces the gate electrode through an insulating film. Therefore, if the width of the p+ type semiconductor region is formed wider, a distance between the p+ type semiconductor region and the insulating film becomes shorter. In this case, a threshold voltage Vth for turning on the semiconductor device may fluctuate. If this threshold voltage Vth fluctuates, a switching operation of the semiconductor device may become unstable.

### BRIEF DESCRIPTION OF THE DRAWINGS

FIG. 1 is a schematic cross-sectional view of a semiconductor device according to a first embodiment.

FIG. 2 is a plan view of a main part of the semiconductor device according to the first embodiment.

FIG. 3A is a cross-sectional view taken along a cutting line A-A shown in FIG. 2.

FIG. 3B is a cross-sectional view taken along a cutting line B-B shown in FIG. 2.

FIG. 4 is a cross-sectional view illustrating a process of simultaneously forming a plurality of first trenches in a first semiconductor layer.

FIG. 5 is a cross-sectional view illustrating a process of laminating an oxide film and an insulating film.

FIG. 6 is a cross-sectional view illustrating a process of removing parts of the insulating film and the oxide film.

FIG. 7 is a cross-sectional view illustrating a process of forming a second trench.

FIG. 8 is a cross-sectional view illustrating a process of forming a sacrificial film.

FIG. 9 is a cross-sectional view illustrating a process of forming a second semiconductor layer, a third semiconductor layer, and a gate electrode.

FIG. 10A is a cross-sectional view illustrating a process of forming a first part of a p+ type semiconductor region below the first trench.

FIG. 10B is a cross-sectional view illustrating a process of forming a second part of the p+ type semiconductor region below the first trench.

FIG. 11A is a cross-sectional view illustrating a process of forming a barrier metal layer in contact with the first part.

FIG. 11B is a cross-sectional view illustrating a process of forming a barrier metal layer in contact with the second part.

FIG. 12A is a cross-sectional view showing a main structure of a semiconductor device according to a second embodiment.

FIG. 12B is a cross-sectional view showing the main structure of the semiconductor device according to the second embodiment.

FIG. 13A is a cross-sectional view showing a main structure of a semiconductor device according to a third embodiment.

FIG. 13B is a cross-sectional view showing the main structure of the semiconductor device according to the third embodiment.

FIG. 14A is a cross-sectional view showing a main structure of a semiconductor device according to a fourth embodiment.

FIG. 14B is a cross-sectional view showing the main structure of the semiconductor device according to the fourth embodiment.

FIG. 15A is a cross-sectional view showing a main structure of a semiconductor device according to a fifth embodiment.

FIG. 15B is a cross-sectional view showing the main structure of the semiconductor device according to the fifth embodiment.

### DETAILED DESCRIPTION

The embodiments of the present invention will be described below with reference to the drawings. These embodiments do not limit the present invention.

### First Embodiment

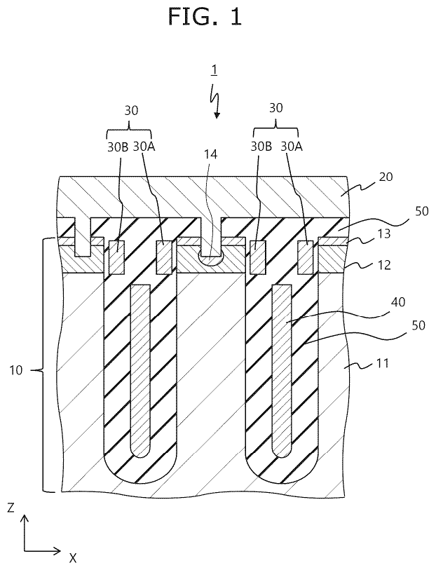

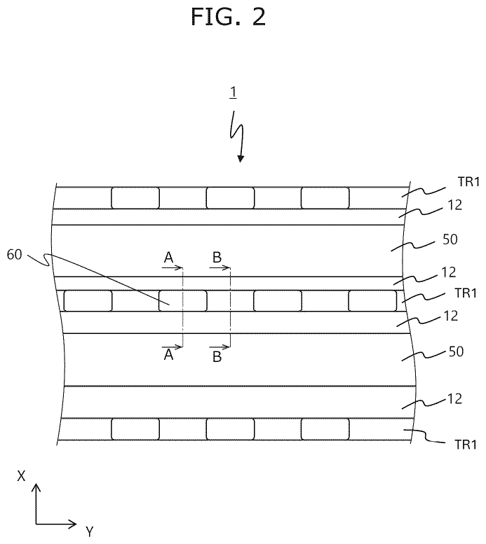

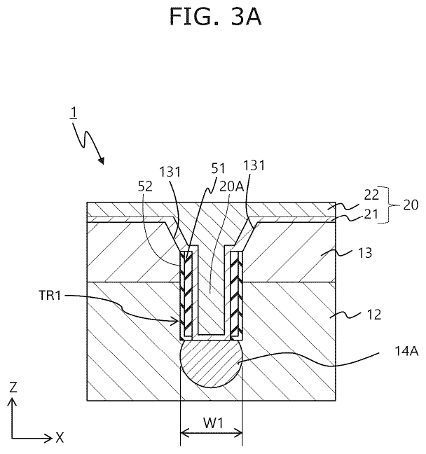

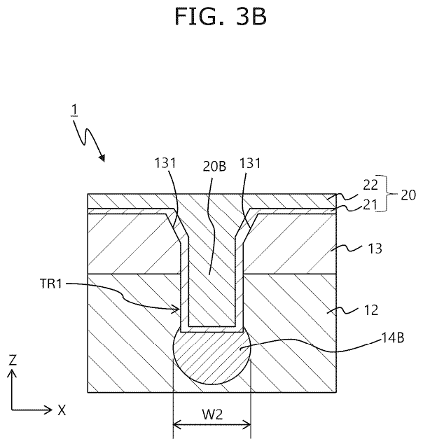

FIG. 1 is a schematic cross-sectional view of a semiconductor device according to a first embodiment. FIG. 2 is a plan view of a main part of the semiconductor device according to the first embodiment. FIG. 3A is a cross-sectional view taken along a cutting line A-A shown in FIG. 2. FIG. 3B is a cross-sectional view taken along a cutting line B-B shown in FIG. 2.

In the following description, the arrangement and configuration of each part of the semiconductor device may be described using an X-axis, a Y-axis, and a Z-axis shown in each figure. The X-axis, the Y-axis, and the Z-axis are mutually orthogonal, representing the X direction, Y direction, and Z direction, respectively. Additionally, the Z direction may be described as upward, and the opposite direction as downward. In this embodiment, the X direction and Y direction correspond to a first direction and a second direction, respectively, representing the in-plane direction parallel to the surface (or back surface) of a semiconductor device 1. The Z direction corresponds to a third direction, representing an out-of-plane direction perpendicular to a surface (or back surface) of the semiconductor device 1.

The notation p and p+ indicates that a concentration of p-type impurities increases in this order. On the other hand, the notation n−, n, and n+ indicates that a concentration of n-type impurities increases in this order. Furthermore, in this embodiment, the p-type and p+ type correspond to a first conductivity type, and the n-type, n type, and n+ type correspond to a second conductivity type.

An impurity concentration can be measured, for example, by SIMS (Secondary Ion Mass Spectrometry). Additionally, the relative high and low impurity concentrations can be determined, for example, from the high and low carrier concentrations obtained by SCM (Scanning Capacitance Microscopy). A depth and other distances of the semiconductor regions can also be determined, for example, by SIMS.

The semiconductor device 1 shown in FIG. 1 is, for example, a MOSFET. This semiconductor device 1 includes a semiconductor part 10, a first electrode 20, a plurality of gate electrodes 30, and a second electrode 40.

The semiconductor part 10 is, for example, composed of a silicon substrate. The semiconductor part 10 includes a first semiconductor layer 11, a second semiconductor layer 12, a third semiconductor layer 13, and a p+ type semiconductor region 14 (a semiconductor region of the first conductivity type).

The first semiconductor layer 11 is an n-type drift layer provided at the bottom layer of the semiconductor part 10. The second semiconductor layer 12 is a p type base layer provided on the first semiconductor layer 11. The third semiconductor layer 13 is an n+ type source layer provided on the second semiconductor layer 12. The third semiconductor layer 13 has a first inclined surface 131 that is inclined in a tapered shape toward the second semiconductor layer 12.

The p+ type semiconductor region 14 includes a first portion 14A shown in FIG. 3A and a second portion 14B shown in FIG. 3B. The first portion 14A and the second portion 14B are alternately provided along the Y direction. The first portion 14A has a first width W1 in the X direction. On the other hand, the second portion 14B has a second width W2 in the Y direction. The first width W1 is smaller than the second width W2.

An upper surface of the first portion 14A is in contact with a first contact portion 20A of the first electrode 20. An outer surface of the first contact portion 20A is covered with an insulating film 51. The outer surface of the insulating film 51 is covered with an oxide film 52. The insulating film 51 is, for example, a silicon nitride (SiN) film. The oxide film 52 is, for example, a silicon oxide (SiO2) film.

An upper surface of the second portion 14B is in contact with a second contact portion 20B of the first electrode 20. A contact area between the second contact portion 20B and the second portion 14B is larger than a contact area between the first contact portion 20A and the first portion 14A.

The first electrode 20 is a source electrode having the first contact portion 20A and the second contact portion 20B. The first electrode 20 has a laminated structure in which a barrier metal layer 21 and a metal layer 22 are laminated. In this laminated structure, the metal layer 22 is formed on the barrier metal layer 21. The material of the barrier metal layer 21 is, for example, titanium nitride (TiN). On the other hand, the material of the metal layer 22 is, for example, tungsten (W). The barrier metal layer 21 includes a portion in contact with the second semiconductor layer 12, a portion in contact with the first inclined surface 131 of the third semiconductor layer 13, and a portion in contact with the insulating film 51. Among these portions, the thickness of the portion in contact with the first inclined surface 131 of the third semiconductor layer 13 is the largest.

In the semiconductor device 1 according to this embodiment, an unillustrated drain electrode is provided at a position facing the first electrode 20 in the Z direction with the semiconductor portion 10 interposed therebetween. When a voltage exceeding the threshold value is applied between each gate electrode 30 and the first electrode 20, a current path is generated from the drain electrode to the first electrode 20 via the semiconductor portion 10. As a result, the semiconductor device 1 switches from an off state to an on state.

The plurality of gate electrodes 30 are arranged in the X direction shown in FIG. 1. Each gate electrode 30 is disposed below the first electrode 20 via an insulating film 50. Further, each gate electrode 30 faces the second semiconductor layer 12 and the third semiconductor layer 13 in the X direction via the insulating film 50. The insulating film 50 functions as a gate insulating film that electrically insulates the gate electrode 30 from the semiconductor portion 10 and the first electrode 20.

Each gate electrode 30 also has a first gate portion 30A and a second gate portion 30B. The first gate portion 30A and the second gate portion 30B are arranged side by side in the X direction via the insulating film 50.

The second electrode 40 is a field plate electrode having a same potential as the first electrode 20. The second electrode 40 is disposed below the gate electrode 30 via the insulating film 50. The material of the second electrode 40 is, for example, polysilicon.

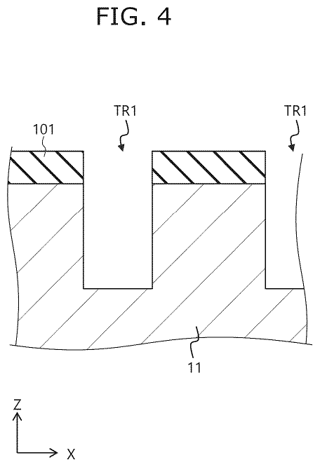

Hereinafter, with reference to FIGS. 4 to 11A and 11B, a method for manufacturing the semiconductor device 1 according to this embodiment will be described. Here, the process up to the formation of the contact portion of the first electrode 20 will be described.

First, as shown in FIG. 4, a plurality of first trenches TR1 are simultaneously formed in the first semiconductor layer 11 so as to be arranged at regular intervals in the X direction. The plurality of first trenches TR1 include first trenches for forming the first contact portions 20A and 20B of the first electrode 20, and second trenches for forming the gate electrodes 30 and the second electrode 40. The first trenches and the second trenches are alternately arranged in the X direction.

The first semiconductor layer 11 is opened at an upper surface and extends in the Z direction, terminating in the middle of the first semiconductor layer 11. In this process, a mask 101 having a pattern with openings at the formation positions of the first trenches TR1 is formed on the upper surface of the first semiconductor layer 11 by CVD (Chemical Vapor Deposition). Subsequently, a plurality of first trenches TR1 are simultaneously formed by RIE (Reactive Ion Etching). Thereafter, the mask 101 is removed.

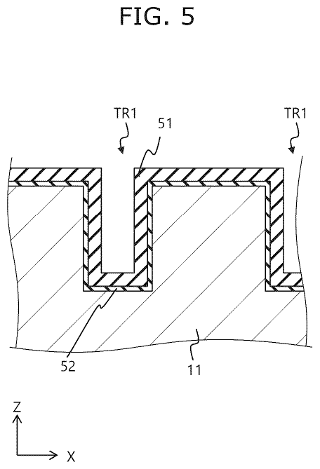

Next, as shown in FIG. 5, the oxide film 52 and the insulating film 51 are laminated in this order on the upper surface of the first semiconductor layer 11 and the inner surfaces of the first trenches TR1. The oxide film 52 can be formed by oxidizing the surface of the first semiconductor layer 11. On the other hand, the insulating film 51 can be formed by, for example, CVD.

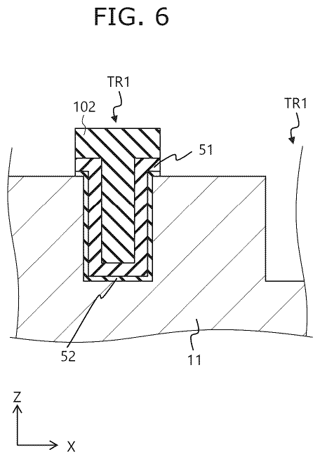

Next, as shown in FIG. 6, the insulating film 51 and the oxide film 52 are removed using a protective film 102 provided in the first trench TR1 for forming the first contact portion 20A and the second contact portion 20B among the plurality of first trenches TR1 as a mask. As a result, the insulating film 51 and the oxide film 52 formed on the inner surface of the first trench TR1 protected by the protective film 102 remain.

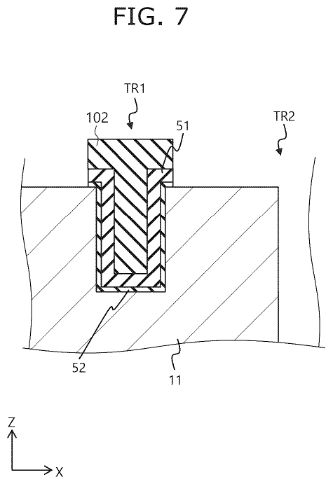

Next, as shown in FIG. 7, the first trench TR1, which is not protected by the protective film 102, is further deepened by RIE to form the second trench TR2. The second trench TR2 corresponds to the second trench for forming the gate electrode 30 and the second electrode 40. Thereafter, the protective film 102 is removed.

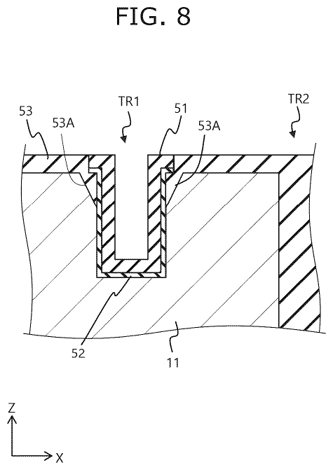

Next, as shown in FIG. 8, a sacrificial film 53 is formed on the upper surface of the first semiconductor layer 11 and in the second trench TR2. When the sacrificial film 53 is, for example, an oxide film, a bird's beak occurs, and the oxidation proceeds to the lower side of the insulating film 51. As a result, the sacrificial film 53 has an inclined portion 53A inclined downward toward the first trench TR1. Thereafter, the sacrificial film 53 is removed. However, a part of the sacrificial film 53 remains as the insulating film 50 in the second trench TR2.

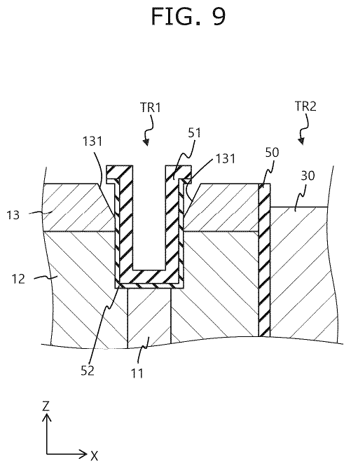

Next, as shown in FIG. 9, the second semiconductor layer 12, the third semiconductor layer 13, and the gate electrode 30 are formed. The second semiconductor layer 12 can be formed by ion implantation and diffusion of p-type impurities into the first semiconductor layer 11. The third semiconductor layer 13 can be formed by ion implantation and diffusion of n-type impurities on the second semiconductor layer 12. Note that the first inclined surface 131 is formed in the third semiconductor layer 13 by removing an inclined portion 53A of the sacrificial film 53. The gate electrode 30 can be formed by filling polysilicon into the second trench TR2. Thereafter, the portions of the insulating film 51 and the oxide film 52 located above the first inclined surface 131 and the portions formed at the bottom of the first trench TR1 are removed by RIE.

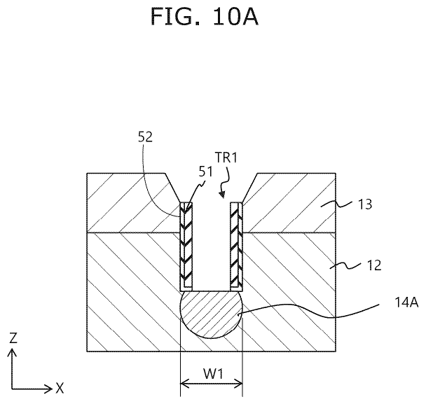

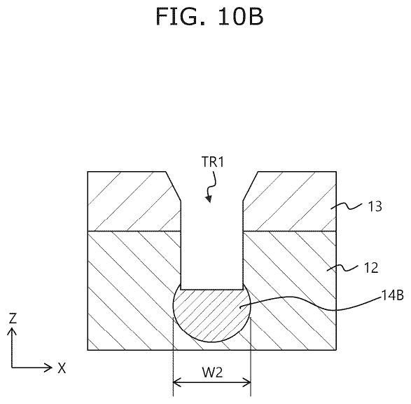

Next, as shown in FIGS. 10A and 10B, the first portion 14A and the second portion 14B of the p+ type semiconductor region 14 are formed below the first trench TR1. The first portion 14A and the second portion 14B can be formed by ion implantation and diffusion of p-type impurities from the first trench TR1.

In the above process, the inner surface of the first trench TR1 located above the second portion 14B does not have the insulating film 51 and the oxide film 52, as shown in FIG. 10B. On the other hand, the inner surface of the first trench TR1 located above the first portion 14A has the insulating film 51 and the oxide film 52, as shown in FIG. 10A. Therefore, the injection range of the p-type impurities is limited by the insulating film 51 and the oxide film 52, so the diffusion of the p-type impurities is suppressed. As a result, the first width W1 of the first portion 14A is smaller than the second width W2 of the second portion 14B.

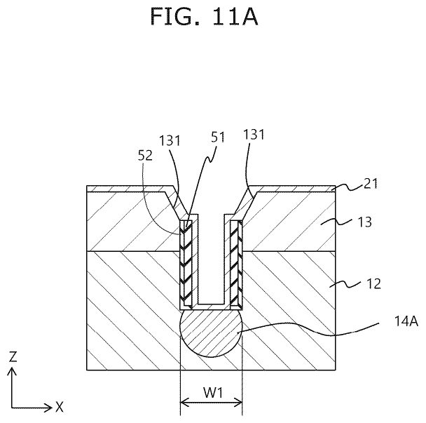

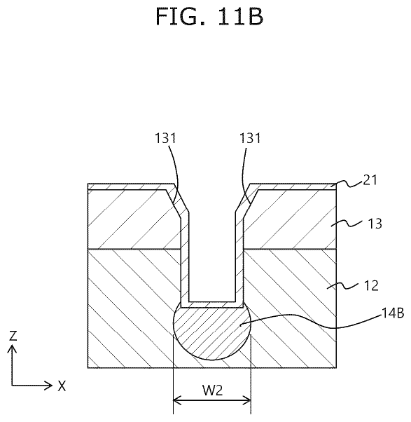

Next, as shown in FIGS. 11A and 11B, a barrier metal layer 21 is formed. In the barrier metal layer 21 formed in this process, the thickness of the portion formed on the first inclined surface 131 of the third semiconductor layer 13 is the largest.

Finally, as shown in FIGS. 3A and 3B, a metal layer 22 is laminated on the barrier metal layer 21.

In the semiconductor device 1 manufactured by the above-described process, the p+ type semiconductor region 14 affects the characteristics of the capacitance Cgs between the gate electrodes 30 and the source electrode (the second electrode 40). The characteristics of the capacitance Cgs affect the threshold voltage Vth of the gate voltage required to turn on the semiconductor device 1. The threshold voltage Vth is affected by the distance in the X direction between the p+ type semiconductor region 14 and the insulating film 50. For example, if this distance is shortened, the threshold voltage Vth fluctuates, which can destabilize the switching characteristics of the semiconductor device 1.

Therefore, in this embodiment, the insulating film 50 formed on the first portion 14A of the p+ type semiconductor region 14 limits the injection range of p-type impurities, so that the first portion 14A is formed narrower in the X direction compared to the second portion 14B. This ensures that the distance in the X direction between the first portion 14A and the insulating film 50 is sufficiently secured, thereby improving the stability of the switching operation.

In this embodiment, the third semiconductor layer 13 has the first inclined surface 131, and the barrier metal layer 21 has the largest thickness at the portion in contact with the first inclined surface 131. This makes it difficult for the first electrode 20 to peel off from the third semiconductor layer 13. Therefore, reliability can be improved.

Furthermore, in the manufacturing process of the semiconductor device 1 according to this embodiment, a plurality of first trenches TR1 are simultaneously formed at regular intervals in the X direction. Thereafter, among the plurality of first trenches TR1, the second trenches TR2 for forming the gate electrode 30 and the second electrode 40 are formed alternately. At this time, the second trenches TR2 are formed by deepening the first trenches TR1. Therefore, compared to the case where the first trenches TR1 and the second trenches TR2 are formed separately from the beginning, the positional deviation of the two trenches is less likely to occur. As a result, the distance in the X direction between the contact portions (the first contact portion 20A and the second contact portion 20B) formed in the first trenches TR1 and the gate electrode 30 formed in the second trenches TR2 is also constant, thereby stabilizing the turn-on operation.

### Second Embodiment

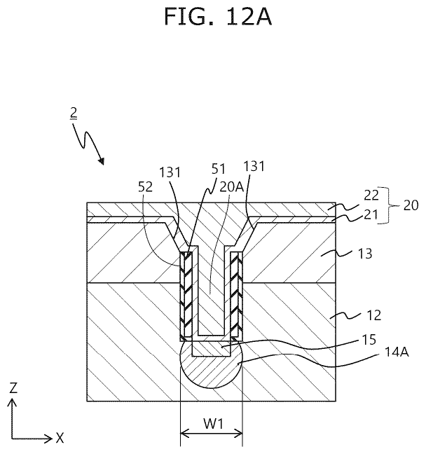

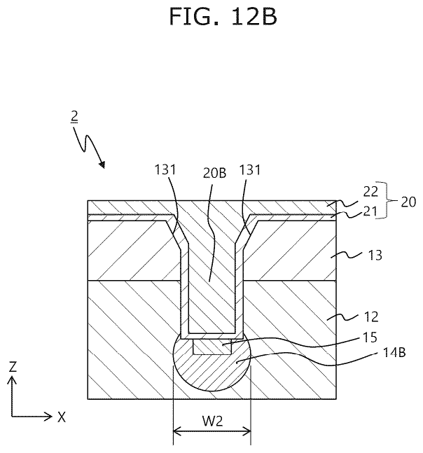

FIGS. 12A and 12B are cross-sectional views showing the main structure of the semiconductor device according to a second embodiment. FIG. 12A shows a cross-section along the same cutting line A-A as FIG. 3A described above. On the other hand, FIG. 12B shows a cross-section along the same cutting line B-B as FIG. 3B described above. Hereinafter, differences from the semiconductor device 1 according to the first embodiment described above will be mainly explained, and redundant explanations will be omitted.

In a semiconductor device 2 according to this embodiment shown in FIG. 12A, a silicide region 15 is in contact with the first electrode 20 (strictly, the barrier metal layer 21) inside the first portion 14A of the p+ type semiconductor region 14. The silicide region 15 is also in contact with the first electrode 20 (strictly, the barrier metal layer 21) inside the second portion 14B.

The silicide region 15 is formed in the process between the process of forming the p+ type semiconductor region 14 and the process of forming the barrier metal layer 21. In this process, platinum (Pt) injected from the first trench TR1 is diffused to form platinum silicide (PtSi) as the silicide region 15.

The semiconductor device 2 according to this embodiment described above includes a body diode. This body diode may function as a freewheeling diode when the semiconductor device 2 is off. In this case, reverse recovery loss (Qrr) occurs.

Therefore, in this embodiment, the silicide region 15 in contact with the first electrode 20 is formed inside the p+ type semiconductor region 14. This shortens the reverse recovery time, thereby reducing the reverse recovery loss.

In the semiconductor device 2 according to this embodiment, as in the first embodiment, the insulating film 50 limits the injection range of p-type impurities for forming the first portion 14A of the p+ type semiconductor region 14. This ensures that the distance in the X direction between the first portion 14A and the insulating film 50 is sufficiently secured, thereby improving the stability of the switching operation.

### Third Embodiment

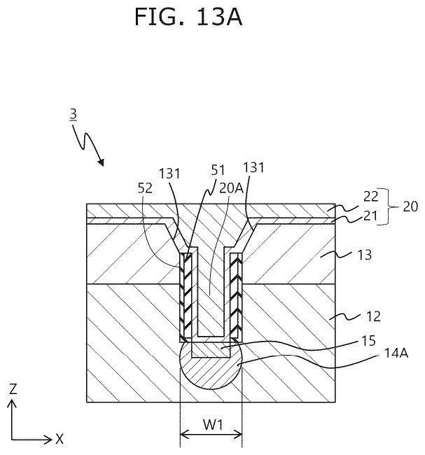

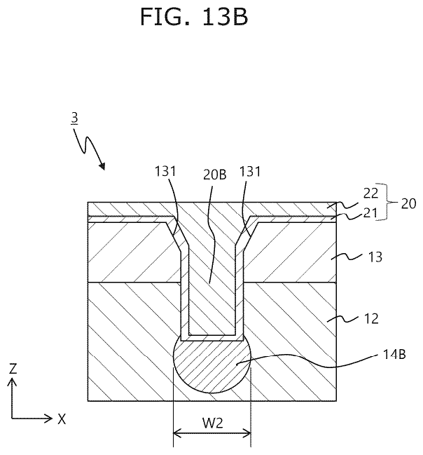

FIGS. 13A and 13B are cross-sectional views showing the main structure of the semiconductor device according to a third embodiment. FIG. 13A shows a cross-section along the same cutting line A-A as FIG. 3A described above. On the other hand, FIG. 13B shows a cross-section along the same cutting line B-B as FIG. 3B described above. Hereinafter, differences from the semiconductor device 1 according to the first embodiment described above will be mainly explained, and redundant explanations will be omitted.

In a semiconductor device 3 according to this embodiment shown in FIG. 13A, the silicide region 15 is provided inside the first portion 14A of the p+ type semiconductor region 14, while it is not provided inside the second portion 14B. Even with such a configuration, the silicide region 15 is in contact with the first electrode 20 (strictly, the barrier metal layer 21) inside at least the first portion 14A. Therefore, it is possible to reduce the reverse recovery loss.

In the semiconductor device 3 according to this embodiment, as in the second embodiment, the insulating film 50 limits the injection range of p-type impurities for forming the first portion 14A of the p+ type semiconductor region 14. This ensures that the distance in the X direction between the first portion 14A and the insulating film 50 is sufficiently secured, thereby improving the stability of the switching operation.

### Fourth Embodiment

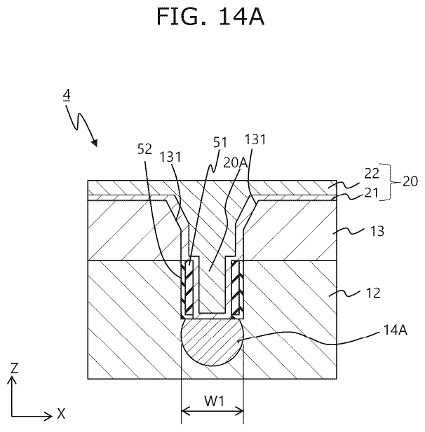

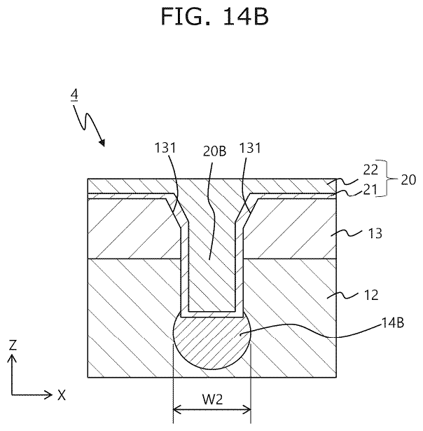

FIGS. 14A and 14B are cross-sectional views showing the main structure of the semiconductor device according to a fourth embodiment. FIG. 14A shows a cross-section along the same cutting line A-A as FIG. 3A described above. On the other hand, FIG. 14B shows a cross-section along the same cutting line B-B as FIG. 3B described above. Hereinafter, differences from the semiconductor device 1 according to the first embodiment described above will be mainly explained, and redundant explanations will be omitted.

In the semiconductor device 4 according to this embodiment shown in FIG. 14A, an upper end positions of the insulating film 51 and the oxide film 52 are different from those in the first embodiment. In the semiconductor device 1 according to the first embodiment, the upper ends of the insulating film 51 and the oxide film 52 are located within the third semiconductor layer 13 (shown in FIG. 3A). As a result, the insulating film 51 and the oxide film 52 cover the first electrode 20 inside the second semiconductor layer 12 and the third semiconductor layer 13.

On the other hand, in the semiconductor device 4 according to this embodiment, the upper ends of the insulating film 51 and the oxide film 52 coincide with the upper end of the second semiconductor layer 12 (shown in FIG. 14A). As a result, the insulating film 51 and the oxide film 52 cover the first electrode 20 inside the second semiconductor layer 12, so the contact area between the third semiconductor layer 13 and the first electrode 20 is larger than in the first embodiment. Therefore, the contact resistance between the third semiconductor layer 13 and the first electrode 20 is reduced compared to the first embodiment. As a result, the on-resistance is reduced, thereby improving the electrical characteristics.

In the semiconductor device 4 according to this embodiment, as in the first embodiment, the insulating film 50 limits the injection range of p-type impurities for forming the first portion 14A of the p+ type semiconductor region 14. This ensures that the distance in the X direction between the first portion 14A and the insulating film 50 is sufficiently secured, thereby improving the stability of the switching operation.

### Fifth Embodiment

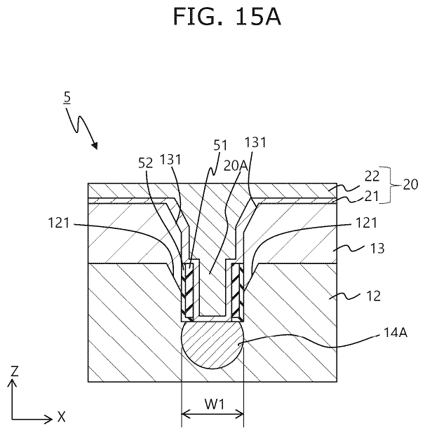

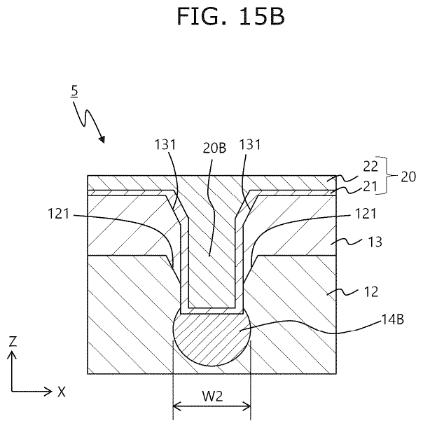

FIGS. 15A and 15B are cross-sectional views showing the main structure of the semiconductor device according to a fifth embodiment. FIG. 15A shows a cross-section along the same cutting line A-A as FIG. 3A described above. On the other hand, FIG. 15B shows a cross-section along the same cutting line B-B as FIG. 3B described above. Hereinafter, differences from the semiconductor device 1 according to the first embodiment described above will be mainly explained, and redundant explanations will be omitted.

In a semiconductor device 5 according to this embodiment shown in FIG. 15A, a second inclined surface 121 is formed on the upper surface of the second semiconductor layer 12 in contact with the third semiconductor layer 13. The second inclined surface 121 is tapered toward the first semiconductor layer 11, similar to the second inclined surface 121 formed in the third semiconductor layer 13. As a result, the contact area between the second semiconductor layer 12 and the third semiconductor layer 13 is larger than in the first embodiment. Therefore, the contact resistance between the second semiconductor layer 12 and the third semiconductor layer 13 is reduced compared to the first embodiment. Consequently, the on-resistance is reduced, thereby improving the electrical characteristics.

In the semiconductor device 5 according to this embodiment, as in the first embodiment, the insulating film 50 limits the injection range of p-type impurities for forming the first portion 14A of the p+ type semiconductor region 14. This ensures that the distance in the X direction between the first portion 14A and the insulating film 50 is sufficiently secured, thereby improving the stability of the switching operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device comprising:
a plurality of gate electrodes arranged along a first direction;
a semiconductor portion including a first conductivity type semiconductor region provided between the plurality of gate electrodes;
a first electrode having a contact portion in contact with the semiconductor region between the plurality of gate electrodes;
wherein the semiconductor region includes a first portion having a first width in the first direction and a second portion provided alternately with the first portion in a second direction orthogonal to the first direction,
wherein the second portion has a second width in the first direction, and
wherein the first width is smaller than the second width.

2. The semiconductor device according to claim 1, further comprising:
an insulating film covering the contact portion on the first portion.

3. The semiconductor device according to claim 2, wherein the insulating film is a silicon nitride film.

4. The semiconductor device according to claim 1, wherein a distance in the first direction between the gate electrode and the contact portion is constant.

5. The semiconductor device according to claim 1, further comprising:
a silicide region in contact with the contact portion inside the first portion.

6. The semiconductor device according to claim 5, wherein the silicide region is in contact with the contact portion inside the second portion.

7. The semiconductor device according to claim 5, wherein the silicide region is platinum silicide.

8. The semiconductor device according to claim 1, further comprising:
a first semiconductor layer of a second conductivity type in the semiconductor portion;
a second semiconductor layer of the first conductivity type provided on the first semiconductor layer, the semiconductor region being disposed in the second semiconductor layer;
a third semiconductor layer of the second conductivity type provided on the second semiconductor layer;
a barrier metal layer provided in the contact portion, the barrier metal layer contacting with the second semiconductor layer and the third semiconductor layer; and
a metal layer provided on the barrier metal layer.

9. The semiconductor device according to claim 8, wherein an upper end of the insulating film is located within the third semiconductor layer.

10. The semiconductor device according to claim 8, wherein an upper end of the insulating film coincides with an upper end of the second semiconductor layer.

11. The semiconductor device according to claim 8, wherein the third semiconductor layer has a first inclined surface tapered toward the second semiconductor layer, and the barrier metal layer has the largest thickness at the portion in contact with the first inclined surface.

12. The semiconductor device according to claim 11, wherein the second semiconductor layer has a second inclined surface tapered toward the first semiconductor layer and in contact with the third semiconductor layer.

13. A method for manufacturing a semiconductor device, comprising:
forming a plurality of first trenches arranged in a first direction in a semiconductor layer;
forming an insulating film on the inner surface of any of the plurality of first trenches;
injecting and diffusing first conductivity type impurities from the plurality of first trenches to form a semiconductor region having a first portion with a first width in the first direction below the trench with the insulating film formed on the inner surface, and a second portion with a second width in the first direction below the trench without the insulating film formed on the inner surface; and
wherein the first width is smaller than the second width.
